(19) United States
(12) Patent Application Publication
(10) Pub. No.: US 2026/0114113 A1
(43) Pub. Date: Apr. 23, 2026

(54) DISPLAY DEVICE, ELECTRONIC DEVICE INCLUDING THE SAME, AND METHOD OF MANUFACTURING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 19/364,362

(22) Filed: Oct. 21, 2025

(30) Foreign Application Priority Data
Oct. 23, 2024 (KR) 10-2024-0145721

(51) Int. Cl. H10K 50/11; H10K 59/12; H10K 59/122

(52) U.S. Cl. CPC H10K 50/11; H10K 59/1201; H10K 59/122

(57) ABSTRACT

A display device includes a substrate including a first pixel area and a second pixel area, a first electrode disposed on the substrate, a first light emitting layer disposed on the first pixel area, a second light emitting layer disposed on the second pixel area, a spacer disposed between the first light emitting layer and the second light emitting layer, an inorganic insulating layer disposed between the first light emitting layer and the spacer and between the second light emitting layer and the spacer, and a second electrode disposed on the first light emitting layer and the second light emitting layer, wherein the spacer and at least one of the first light emitting layer and the second light emitting layer include a same material.

### CROSS-REFERENCE TO RELATED APPLICATION

This application claims priority to and benefits of Korean Patent Application No. 10-2024-0145721 under 35 U.S.C. § 119, filed on Oct. 23, 2024, in the Korean Intellectual Property Office, the entire contents of which are incorporated herein by reference.

### BACKGROUND

### 1. Technical Field

Embodiments relate to a display device, an electronic device including the display device, and a method of manufacturing the display device and the electronic device, and more specifically, to a display device capable of stable implementation and a method of manufacturing the display device and the electronic device.

### 2. Description of the Related Art

A light emitting display device LED has a light emitting element including a hole injection electrode, an electron injection electrode, and a light emitting layer formed therebetween, and is a self-luminous display device that emits light in case that excitons generated by a combination of holes injected from the hole injection electrode and electrons injected from the electron injection electrode in the light emitting layer drop from an excited state to a ground state.

### SUMMARY

The embodiments provide a display device, an electronic device including the display device, and a method of manufacturing the display device and the electronic device, addressing the issues of second electrode disconnection and current leakage, while ensuring reliable implementation without moisture absorption problems even during an outdoor exposure process.

However, embodiments are not limited to those set forth herein. The above and other embodiments will become more apparent to one of ordinary skill in the art to which the disclosure pertains by referencing the detailed description of the disclosure given below.

A display device according to an embodiment includes a substrate including a first pixel area and a second pixel area, a first electrode disposed on the substrate, a first light emitting layer disposed on the first pixel area, a second light emitting layer disposed on the second pixel area, a spacer disposed between the first light emitting layer and the second light emitting layer, an inorganic insulating layer disposed between the first light emitting layer and the spacer and between the second light emitting layer and the spacer, and a second electrode disposed on the first light emitting layer and the second light emitting layer, wherein the spacer and at least one of the first light emitting layer and the second light emitting layer include a same material.

Side surfaces of the first light emitting layer and the second light emitting layer may form an inclination angle in a range of about 70° C. to about 90° C. with respect to the substrate.

The spacer may have a glass transition temperature lower than those of the first light emitting layer and the second light emitting layer.

The glass transition temperature of the spacer may be in a range of about 90° C. and about 100° C.

The first light emitting layer may include at least one of a first hole injection layer, a first hole transport layer, a first main light emitting layer, a first electron transport layer, and a first electron injection layer.

The second light emitting layer may include at least one of a second hole injection layer, a second hole transport layer, a second main light emitting layer, a second electron transport layer, and a second electron injection layer.

The spacer and at least one of the first hole injection layer, the first hole transport layer, the first main light emitting layer, the first electron transport layer, the first electron injection layer, the second hole injection layer, the second hole transport layer, the second main light emitting layer, the second electron transport layer, and the second electron injection layer may include a same material.

The spacer may be in a form of filling the inorganic insulating layer.

The spacer may include at least one of a triphenylamine compound, a carbazole, an aromatic amine compound, an anthracene compound, a hydroxyquinoline, and an iridium complex.

The spacer may not contain oxygen.

An upper surface of the spacer may be downwardly concave without a step from the first light emitting layer and the second light emitting layer.

The upper surface of the spacer may be disposed lower than upper surfaces of the first light emitting layer and the second light emitting layer.

The second electrode may be in a form that covers the first light emitting layer, the second light emitting layer, and the spacer.

According to an embodiment, a method of manufacturing the display device includes preparing a substrate including a first pixel area and a second pixel area, forming a first electrode on the substrate, forming a first light emitting layer overlapping the first pixel area on the first electrode, and a first sacrificial layer disposed on the first light emitting layer, forming a second light emitting layer overlapping the second pixel area on the first electrode, and a second sacrificial layer disposed on the second light emitting layer, forming an inorganic insulating layer between the first light emitting layer and the second light emitting layer, forming a spacer material layer on the first and second sacrificial layers and the inorganic insulating layer, forming a spacer between the first light emitting layer and the second light emitting layer through a reflow process, removing the spacer material layer remaining on the first sacrificial layer and the second sacrificial layer, removing the first sacrificial layer and the second sacrificial layer, and forming a second electrode on the first light emitting layer, the second light emitting layer, and the spacer, wherein the spacer and at least one of the first light emitting layer and the second light emitting layer include a same material.

The forming of the spacer between the first light emitting layer and the second light emitting layer through a reflow process may include filling a space between the first light emitting layer and the second light emitting layer with at least a portion of the spacer material layer having flowability, and the reflow process may be performed at a temperature lower than a glass transition temperature of the first light emitting layer and the second light emitting layer and higher than a glass transition temperature of the spacer forming layer.

The first light emitting layer may include at least one of a first hole injection layer, a first hole transport layer, a first main light emitting layer, a first electron transport layer, and a first electron injection layer, the second light emitting layer may include at least one of a second hole injection layer, a second hole transport layer, a second main light emitting layer, a second electron transport layer, and a second electron injection layer, and the spacer and at least one of the first hole injection layer, the first hole transport layer, the first main light emitting layer, the first electron transport layer, the first electron injection layer, the second hole injection layer, the second hole transport layer, the second main light emitting layer, the second electron transport layer, and the second electron injection layer may include the same material.

The forming of the first light emitting layer and the first sacrificial layer overlapping the first pixel area on the first electrode includes stacking a first light emitting material layer on the first electrode, stacking a first sacrificial material layer on the first light emitting material layer, and forming the first light emitting material layer and the first sacrificial material layer, and the forming of the second light emitting layer and the second sacrificial layer overlapping the second pixel area on the first electrode includes depositing a second light emitting material layer on the first electrode, depositing a second sacrificial material layer on the second light emitting material layer, and patterning the second light emitting material layer and the second sacrificial material layer to form the second light emitting layer and the second sacrificial layer, and side surfaces of the first light emitting layer and the second light emitting layer may form an inclination angle of about 70° to about 90° with respect to the substrate.

The spacer may include at least one selected from a group consisting of a triphenylamine compound, carbazole, an aromatic amine compound, an anthracene compound, hydroxyquinoline, and an iridium complex.

The spacer may not contain oxygen O.

According to an embodiment, an electronic device includes: a processor that provides input image data; and a display device that displays an image based on the input image data, the display device including: a substrate including a first pixel area and a second pixel area; a first electrode disposed on the substrate; a first light emitting layer disposed on the first pixel area; a second light emitting layer disposed on the second pixel area; a spacer disposed between the first light emitting layer and the second light emitting layer; an inorganic insulating layer disposed between the first light emitting layer and the spacer, and between the second light emitting layer and the spacer, and a second electrode disposed on the first light emitting layer and the second light emitting layer, wherein the spacer and at least one of the first light emitting layer and the second light emitting layer include a same material.

The display device according to an embodiment may achieve high resolution, and problems of a short circuit and current leakage of the second electrode are improved, enabling stable implementation.

The display device according to an embodiment may be manufactured at a low temperature and has no moisture absorption problem even during an exposure process to the outside air, so stable implementation is possible.

### BRIEF DESCRIPTION OF THE DRAWINGS

FIG. 1 is a schematic perspective view illustrating a state of use of a display device according to an embodiment.

FIG. 2 is an exploded schematic perspective view of a display device according to an embodiment.

FIG. 3 is a schematic plan view illustrating a portion of the display area.

FIG. 4 is a schematic cross-sectional view of a display area in a display device according to an embodiment.

FIG. 5 is a schematic cross-sectional view of a light emitting element.

FIGS. 6 and 7 are schematic cross-sectional views of a display area in a display device according to an embodiment.

FIGS. 8 to 21 are schematic cross-sectional process views sequentially showing a method of manufacturing a display device according to an embodiment.

FIG. 22 is a block diagram of an electronic device according to an embodiment.

FIG. 23 shows schematic diagrams of electronic devices according to various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

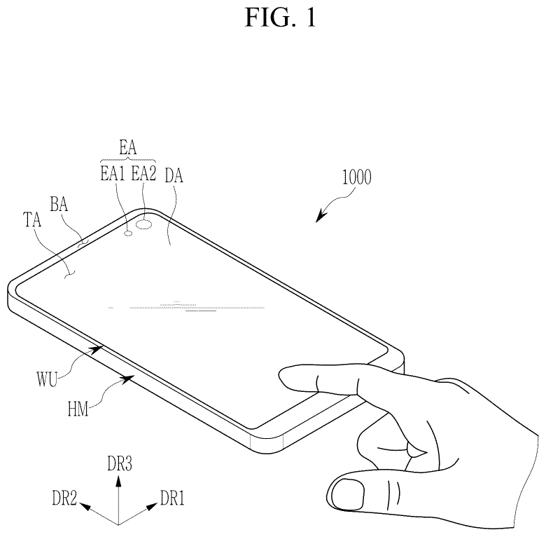

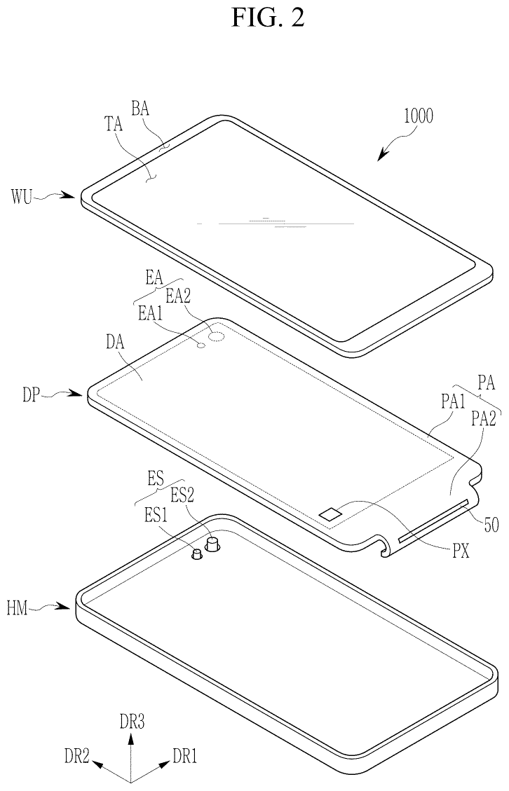

Below, the structure of the display device will be illustrated schematically with reference to FIGS. 1 and 2. FIG. 1 is a schematic perspective view showing a state of use of a display device according to an embodiment, and FIG. 2 is an exploded schematic perspective view of the display device according to an embodiment.

Referring to FIG. 1, a display device 1000 according to an embodiment may be a device that displays a moving image or a still image, and may be used as a display screen for various products such as portable electronic devices such as a mobile phone, a smart phone, a tablet personal computer (PC), a mobile communication terminal, an electronic notebook, an electronic book, a portable multimedia player (PMP), a navigation device, an ultramobile PC (UMPC), and the like, as well as televisions, laptops, monitors, billboards, and the Internet of Things (IOT). For example, the display device 1000 according to an embodiment may be used in a wearable device such as a smartwatch, a watch phone, a glasses type display, and a head mounted display (HMD). For example, the display device 1000 according to an embodiment may be used as a center information display (CID) positioned on a dashboard of a car, a center fascia or dashboard of a car, a room mirror display replacing a side mirror of a car, and a display positioned on the back of a front seat as entertainment for the rear seat of a car. For convenience of explanation, FIG. 1 illustrates the display device 1000 being used as a smartphone.

The display device 1000 may display an image in a third direction DR3 on a display surface parallel to each of a first direction DR1 and a second direction DR2. The display surface on which the image is displayed may correspond to the front surface of the display device 1000 and may correspond to the front surface of the cover window WU. Images may include still images as well as moving images.

In this embodiment, the front surface (or upper surface) and back surface (or lower surface) of each member may be defined based on the direction in which the image is displayed. The front and back surfaces may be opposite each other in the third direction DR3, and the normal direction of each of the front and back surfaces may be parallel to the third direction DR3. The separation distance in the third direction DR3 between the front and back surfaces may correspond to the thickness of the display panel in the third direction DR3.

The display device 1000 according to an embodiment may detect an externally applied user input (see a hand in FIG. 1). User input may include various forms of external input, such as parts of the user's body, light, heat, or pressure. In an embodiment, the user's input is depicted as the user's hand being applied to the front. However, embodiments are not limited thereto. The user's input may be provided in various forms, and furthermore, the display device 1000 may detect the user's input applied to the side or back of the display device 1000 according to the structure of the display device 1000.

Referring to FIGS. 1 and 2, the display device 1000 may include a cover window WU, a housing HM, a display panel DP, and an optical element ES. In an embodiment, the cover window WU and the housing HM may be combined to form the exterior of the display device 1000.

The cover window WU may include an insulating panel. For example, the cover window WU may be composed of glass, plastic, or a combination thereof.

The front of the cover window WU may define the front of the display device 1000. A transmission area TA may be an optically transparent area. For example, the transmission area TA may be an area having a visible light transmittance of greater than about 90%.

A blocking area BA may define the shape of the transmission area TA. The blocking area BA may be adjacent to the transmission area TA and may surround the transmission area TA. The blocking area BA may be an area with relatively low light transmittance compared to the transmission area TA. The blocking area BA may include an opaque material that blocks light. The blocking area BA may have a selectable color. The blocking area BA may be defined by a bezel layer provided separately from the transparent substrate defining the transmission area TA, or by an ink layer formed by inserting or coloring the transparent substrate.

The display panel DP may include pixels PX that display an image and a driver 50, and the pixels PX may be positioned within a display area DA and a component area EA. The display panel DP may include a front surface including the display area DA and a non-display area PA. In an embodiment, the display area DA and the component area EA may be areas where an image is displayed, including pixels, and at the same time, may be areas where a touch sensor is positioned above the pixels in the third direction DR3 to detect external input.

The transmission area TA of the cover window WU may at least partially overlap the display area DA and the component area EA of the display panel DP. For example, the transmission area TA may overlap the front surface of the display area DA and the component area EA, or may overlap at least a portion of the display area DA and the component area EA. Accordingly, the user may view the image through the transmission area TA or provide external input based on the image. However, embodiments are not limited thereto. For example, the area where the image is displayed and the area where external input is detected may be separated from each other.

The non-display area PA of the display panel DP may at least partially overlap the blocking area BA of the cover window WU. The non-display area PA may be an area covered by the blocking area BA. The non-display area PA may be adjacent to the display area DA and may surround the display area DA. The non-display area PA may not display images, and drive circuits or drive wiring for driving the display area DA may be positioned there. The non-display area PA may include a first peripheral area PA1 where the display area DA is positioned on the outside and a second peripheral area PA2 including a driver 50, a connecting wire, and a bending area. In the embodiment of FIG. 2, the first peripheral area PA1 may be positioned on three sides of the display area DA, and the second peripheral area PA2 may be positioned on the one remaining side of the display area DA.

In an embodiment, the display panel DP may be assembled in a flat state with the display area DA, the component area EA, and the non-display area PA facing the cover window WU. However, embodiments are not limited thereto. A portion of the non-display area PA of the display panel DP may be bent. For example, a part of the non-display area PA may be directed toward the back surface of the display device 1000, so that the blocking area BA visible on the front surface of the display device 1000 may be reduced, and in FIG. 2, the second peripheral area PA2 may be bent and positioned on the back surface of the display area DA and then assembled.

For example, the component area EA of the display panel DP may include a first component area EA1 and a second component area EA2. The first component area EA1 and the second component area EA2 may be at least partially surrounded by the display area DA. The first component area EA1 and the second component area EA2 are depicted as being spaced apart from each other, and may be at least partially connected. However, embodiments are not limited thereto. The first component area EA1 and the second component area EA2 may be areas in which optical elements (see ES of FIG. 2; also referred to as components hereinafter) that utilize infrared rays, visible light, or sound are positioned thereunder.

The display area (DA; also referred to as the main display area hereinafter) and the component area EA may be formed with light emitting diodes and circuits that generate and transmit light-emitting current to each of the light emitting diodes. For example, one light emitting diode and one pixel circuit are referred to as a pixel PX. In the display area DA and the component area EA, one pixel circuit unit and one light emitting diode may be formed on a one-to-one basis.

The first component area EA1 may include a transparent portion that is transparent to light and/or sound and a display portion that includes pixels. The transparent area may be positioned between adjacent pixels and may be composed of a layer through which light and/or sound pass. The transparent portion may be positioned between adjacent pixels, and in some embodiments, a non-transparent layer, such as a light blocking member, may overlap the first component area EA1. The number of pixels per unit area (hereinafter also referred to as resolution) of pixels included in the display area DA (hereinafter also referred to as normal pixels) and the number of pixels per unit area of pixels included in the first component area EA1 (hereinafter also referred to as first component pixels) may be the same.

The second component area EA2 may include an area (hereinafter also referred to as a light transmission area) formed of a transparent layer that allows light to pass through, and the light transmission area may not have a conductive layer or a semiconductor layer positioned thereon, and may have a structure that does not block light by including an opening where a layer including a light blocking material, for example, a pixel defining layer and/or a light blocking member, overlaps a position corresponding to the second component area EA2. The number of pixels per unit area of pixels included in the second component area EA2 (hereinafter also referred to as second component pixels) may be smaller than the number of pixels per unit area of normal pixels included in the display area DA. Thus, the resolution of the second component pixels may be lower than the resolution of normal pixels.

The second peripheral area PA2 may include a bending portion. The display area DA and the first peripheral area PA1 may have a flat state substantially parallel to a plane defined by the first direction DR1 and the second direction DR2, and one side of the second peripheral area PA2 may extend from a flat state, pass through a bend, and then be in a flat state again. Thus, at least a portion of the second peripheral area PA2 may be bent and assembled to be positioned on the back side of the display area DA. At least a portion of the second peripheral area PA2 may overlap the display area DA on a plane when assembled, so that the blocking area BA of the display device 1000 may be reduced. However, embodiments are not limited thereto. For example, the second peripheral area PA2 may not be bent.

The driver 50 may be mounted on the second peripheral area PA2, and may be mounted on the bending unit or positioned on either side of the bending unit. The driver 50 may be provided in the form of a chip.

The driver 50 may be electrically connected to the display area DA and the component area EA and may transmit electrical signals to pixels in the display area DA and the component area EA. For example, the driver 50 may provide data signals to the pixels PX positioned in the display area DA. In another example, the driver 50 may include a touch driving circuit and may be electrically connected to a touch sensor TS positioned in the display area DA and/or the component area EA. For example, the driver 50 may be designed to include various circuits in addition to the circuits described above or to provide various electrical signals to the display area DA.

For example, the display device 1000 may have a pad portion positioned at the end portion of the second peripheral area PA2 and may be electrically connected to a flexible printed circuit board FPCB including a driving chip through the pad portion. For example, the driving chip positioned on the flexible printed circuit board may include various driving circuits for driving the display device 1000 or connectors for power supply. In some embodiments, a rigid printed circuit board (PCB) may be used instead of a flexible printed circuit board.

The optical element ES may be positioned at the bottom of the display panel DP. The optical element ES may include a first optical element ES1 overlapping the first component area EA1 and a second optical element ES2 overlapping the second component area EA2. The first optical element ES1 may also use infrared light, and the first component area EA1 may be overlapped by a layer that does not transmit light, such as a light blocking member.

The first optical element ES1 may be an electronic element that utilizes light or sound. For example, the first optical element ES1 may be a sensor that receives and utilizes light, such as an infrared sensor, a sensor that outputs and detects light or sound to measure distance or recognize fingerprints, a small lamp that outputs light, or a speaker that outputs sound. In the case of electronic elements that utilize light, light of various wavelengths, such as visible light, infrared light, and ultraviolet light, may be utilized.

The second optical element ES2 may be at least one of a camera, an infrared (IR) camera, a dot projector, an IR illuminator, and a time-of-flight sensor (ToF sensor).

The housing HM may be combined with a cover window WU. The cover window WU may be positioned on the front of the housing HM. The housing HM may be combined with the cover window WU to provide a predetermined (or certain) accommodation space. The display panel DP and the optical element ES may be accommodated in a predetermined accommodation space provided between the housing HM and the cover window WU.

The housing HM may comprise a material having relatively high stiffness. For example, the housing HM may include frames and/or plates made of glass, plastic, or metal, or a combination thereof. The housing HM may reliably protect the components of the display device 1000 accommodated in the internal space from external impact.

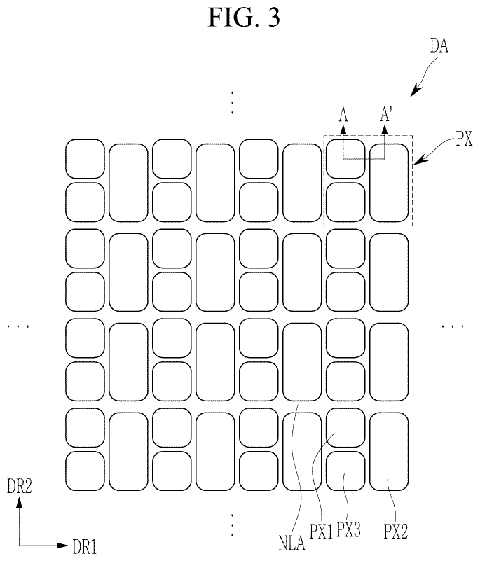

Hereinafter, with reference to FIG. 3, a shape of a pixel PX positioned in the display area DA in the display device according to an embodiment will be examined.

FIG. 3 is a schematic plan view illustrating a portion of the display area.

The display device according to an embodiment may include pixels PX positioned in the display area DA. The pixels PX may include a first pixel area PX1, a second pixel area PX2, and a third pixel area PX3 that display different colors. For example, the pixels PX may include the first pixel area PX1 that emits red light, the second pixel area PX2 that emits blue light, and the third pixel area PX3 that emits green light.

The first pixel area PX1, the second pixel area PX2, and the third pixel area PX3 may be repeatedly positioned along the first direction DR1 and the second direction DR2. For example, as illustrated in FIG. 3, a first pixel area PX1 and a second pixel area PX2 may be alternately positioned, and a third pixel area PX3 and a second pixel area PX2 may be alternately positioned along the first direction DR1. For example, the first pixel area PX1 and the third pixel area PX3 may be alternately positioned in one column along the second direction DR2, and the second pixel area PX2 may be repeatedly positioned in another column adjacent thereto. The arrangement form of the pixels is not limited to this arrangement form, and the first pixel area PX1, the second pixel area PX2, and the third pixel area PX3 may be positioned in various forms.

The display device according to an embodiment may include a non-light emitting area NLA that does not overlap a first pixel area PX1, a second pixel area PX2, and a third pixel area PX3 in a display area DA. The non-light emitting area NLA may be positioned so as to be spaced apart from the first pixel area PX1, the second pixel area PX2, and the third pixel area PX3. A non-light emitting area NLA may be positioned between adjacent first pixel areas PX1, second pixel areas PX2, and third pixel areas PX3.

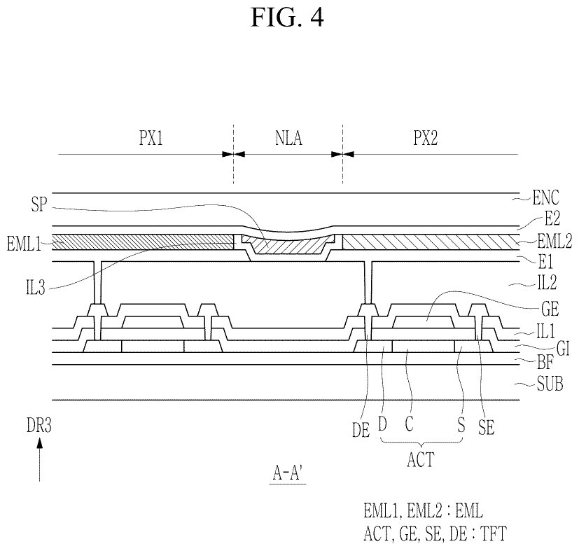

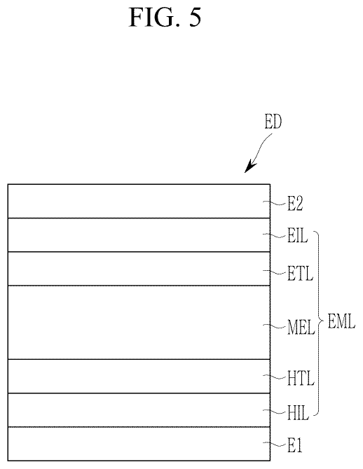

Hereinafter, with reference to FIGS. 4 to 7, the structure of a display area in the display device according to an embodiment will be examined. FIGS. 4, 6 and 7 are schematic cross-sectional views of a display area in the display device according to an embodiment. FIG. 5 is a schematic cross-sectional diagram of a light emitting element.

First, referring to FIG. 4, a substrate SUB may include a material having rigid properties, such as glass, or a flexible material that is bent, such as plastic or polyimide. Referring to FIG. 4 together with FIG. 3, the substrate SUB may include a first pixel area PX1, a second pixel area PX2, a third pixel area PX3, and a non-light emitting area NLA.

A buffer layer BF may be positioned on the substrate SUB. The buffer layer BF may include an inorganic material, such as silicon nitride SiNₓ, silicon oxide SiOₓ, or silicon oxynitride SiOₓN_{y}. According to the embodiment, the buffer layer BF may be a single-layer structure or a multi-layer structure including the inorganic insulating material.

A semiconductor layer ACT may be positioned on top (or upper surface) of the buffer layer BF. The semiconductor layer ACT may include any one of amorphous silicon, polycrystalline silicon, and an oxide semiconductor. For example, the semiconductor layer ACT may include low-temperature polysilicon LTPS or an oxide semiconductor including at least one of zinc (Zn), indium (In), gallium (Ga), tin (Sn), and mixtures thereof. For example, the semiconductor layer ACT may include indium-gallium-zinc oxide (IGZO). The semiconductor layer ACT may include a channel region C, a source region S, and a drain region D that are distinguished according to whether or not they are doped with impurities. The source region S and drain region D may have conductive characteristics corresponding to the conductor.

A gate insulating layer GI may be positioned on top (or upper surface) of the semiconductor layer ACT. The gate insulating layer GI may cover the semiconductor layer ACT and the substrate SUB. The gate insulating layer GI may include an inorganic insulating material such as silicon nitride SiNₓ, silicon oxide SiOₓ, or silicon oxynitride SiOₓN_{y}. The gate insulating layer GI may be a single-layer structure or a multi-layer structure containing the inorganic insulating materials.

A gate electrode GE may be positioned on the gate insulating layer GI. The gate electrode GE may include a metal or metal alloy such as copper (Cu), molybdenum (Mo), aluminum (Al), silver (Ag), chromium (Cr), tantalum (Ta), or titanium (Ti). The gate electrode GE may be a single-layer structure or a multi-layer structure. The region overlapping the planar gate electrode GE among the semiconductor layers (ACT) may be the channel region C.

A first insulating layer IL1 may be positioned on the gate electrode GE. The first insulating layer IL1 may include an inorganic insulating material such as silicon nitride SiNₓ, silicon oxide SiOₓ, or silicon oxynitride SiOₓN_{y}. The first insulating layer IL1 may be a single-layer structure or a multi-layer structure containing the inorganic insulating material.

The source electrode SE and the drain electrode DE may be positioned on the first insulating layer IL1. The source electrode SE and the drain electrode DE may be electrically connected to the source region S and the drain region D of the semiconductor layer ACT through openings positioned in the first insulating layer IL1 and the gate insulating layer GI, respectively. Accordingly, the aforementioned semiconductor layer ACT, the gate electrode GE, the source electrode SE, and the drain electrode DE may form one transistor TFT. In some embodiments, the transistor TFT may include only a source region and a drain region of the semiconductor layer ACT instead of the source electrode SE and the drain electrode DE.

The source electrode SE and drain electrode DE may include a metal or metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The source electrode SE and the drain electrode DE may be a single-layer structure or a multi-layer structure. According to another embodiment, the source electrode SE and the drain electrode DE may be composed of a triple layer including an upper layer, a middle layer, and a lower layer, and the upper layer and the lower layer may include titanium (Ti), and the middle layer may include aluminum (Al).

A second insulating layer IL2 may be positioned over the source electrode SE and the drain electrode DE. The second insulating layer IL2 may cover the source electrode SE and the drain electrode DE. The second insulating layer IL2 may be for planarizing the surface of the substrate SUB equipped with the transistor TFT, and may be an organic insulating film, and may include one or more materials selected from the group consisting of polyimide, polyamide, acrylic resin, benzocyclobutene, and phenol resin.

A first electrode E1 may be positioned on the second insulating layer IL2. The first electrode E1 may be also referred to as an anode electrode and may be composed of a single layer or multiple layers including a transparent conductive oxide film or a metal material. The transparent conductive oxide film may include indium-tin-oxide (ITO), poly-ITO, indium-zinc-oxide (IZO), indium-gallium-zinc-oxide (IGZO), and indium-tin-zinc-oxide (ITZO). The metal material may include at least one of silver (Ag) and aluminum (Al). For example, the first electrode E1 may have a three-layer structure of ITO/Ag/ITO. Referring to FIG. 4 together with FIG. 3, the center portion of the first electrode E1 may overlap the first pixel area PX1 and the second pixel area PX2, and the edge portion of the first electrode E1 may overlap the non-light emitting area NLA.

The first electrode E1 may be physically and electrically connected to the drain electrode DE through the opening of the second insulating layer IL2. Accordingly, the first electrode E1 may receive an output current to be transmitted from the drain electrode DE to the light emitting layer EML to be described later.

A light emitting layer EML may be positioned on the first electrode E1. The light emitting layer EML may overlap the center portion of the first electrode E1 and may not overlap the edge portion of the first electrode E1. A side surface of the light emitting layer EML may have a high slope in a cross-sectional view, for example, an inclination angle of about 70° to about 90°, or about 90°, with respect to the substrate SUB.

The light emitting layer EML may include organic or inorganic materials that emit light such as red, green, or blue. The light emitting layer EML that emits red, green, or blue light may include a small-molecule or large-molecule organic material. In some embodiments, the light emitting layer EML may include quantum dots. Quantum dots (also referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or a combination thereof. The quantum dots may not contain cadmium.

The light emitting layer EML may overlap each of the first pixel area PX1, the second pixel area PX2, and the third pixel area PX3. The display device according to an embodiment may include a first light emitting layer EML1 overlapping the first pixel area PX1, a second light emitting layer EML2 overlapping the second pixel area PX2, and a third light emitting layer overlapping the third pixel area PX3. For example, the first light emitting layer EML1 may emit red light, the second light emitting layer EML2 may emit blue light, and the third light emitting layer may emit green light.

Referring to FIG. 5, a light emitting layer EML may include a main light emitting layer MEL and auxiliary layers including an electron injection layer EIL, an electron transport layer ETL, a hole transport layer HTL, and a hole injection layer HIL. For example, the first light emitting layer EML1 may include a first hole injection layer, a first hole transport layer, a first main light emitting layer, a first electron transport layer, and a first electron injection layer. The second light emitting layer EML2 may include a second hole injection layer, a second hole transport layer, a second main light emitting layer, a second electron transport layer, and a second electron injection layer.

The light emitting layer EML may include at least one of a triphenylamine compound, a carbazole, an aromatic amine compound, an anthracene compound, hydroxyquinoline, and an iridium complex. For example, the main light emitting layer MEL may include at least one of an anthracene compound, a triphenyl amine compound, and an iridium complex. The hole injection layer HIL and the hole transport layer HTL may include at least one of a triphenylamine-based compound and a carbazole, the electron transport layer ETL may include at least one of an anthracene-based compound and an aromatic amine-based compound, and the electron injection layer EIL may include hydroxyquinoline.

The first electrode E1, the light emitting layer EML, and the second electrode E2 may form a light emitting element ED.

Referring to FIG. 4, an inorganic insulating layer IL3 and a spacer SP may be positioned on the first electrode E1 and the second insulating layer IL2. The inorganic insulating layer IL3 and the spacer SP may be positioned between the first light emitting layer EML1 and the adjacent second light emitting layer EML2. The inorganic insulating layer IL3 and the spacer SP may overlap the non-light emitting area NLA.

The spacer SP may be positioned between the first light emitting layers EML1 and the adjacent second light emitting layers EML2. As illustrated in FIG. 4, the spacer SP may be in a form that fills the space between the adjacent first light emitting layer EML1 and the second light emitting layer EML2. Therefore, the spacer SP may physically separate the first light emitting layer EML1 and the second light emitting layer EML2 and provide electrical insulation, thereby preventing problems such as current leakage.

The inorganic insulating layer IL3 may be positioned between the first light emitting layer EML1, the second light emitting layer EML2 and the spacer SP. The inorganic insulating layer IL3 may be positioned between the first light emitting layer EML1 and the spacer SP, and may be positioned between the second light emitting layer EML2 and the spacer SP. The inorganic insulating layer IL3 may have a form that is in contact with the second insulating layer IL2, the first electrode E1, and the adjacent light emitting layers EML1 and EML2 and surrounds at least a portion of the spacer SP.

The spacers SP may have various forms. Referring to FIG. 4, the spacer SP may be positioned on the inorganic insulating layer IL3 and may be in a form that fills the step formed by the inorganic insulating layer IL3. An upper surface of the spacer SP may have substantially no step difference from the adjacent light emitting layers EML1 and EML2 and may have a downwardly concave shape. The opposite end portions of the upper surface of the spacer SP may be coplanar with the adjacent light emitting layers EML1 and EML2. The spacer SP may have a lower glass transition temperature than the light emitting layer EML. The glass transition temperature of the spacer SP may be about 100° C. or less, for example about 90° C. to about 100° C.

The spacer SP and at least one of the first light emitting layer EML1 and the second light emitting layer EML2 may include the same material. For example, the spacer SP and at least one of the first hole injection layer, the first hole transport layer, the first main light emitting layer, the first electron transport layer, and the first electron injection layer may include the same material. For example, the spacer SP and at least one of the second hole injection layer, the second hole transport layer, the second main light emitting layer, the second electron transport layer, and the second electron injection layer may include the same material.

The spacer SP may include at least one of a triphenylamine compound, carbazole, an aromatic amine compound, an anthracene compound, hydroxyquinoline, and an iridium complex.

For example, the spacer SP may include at least one selected from a group consisting of HT01, HT211, TC1558, IDE105, TPAP, Alq3, BeBq2, LiQ, F2IrPic, IrPPy3, CBP, TMM019, and RD61, each of which is represented by the chemical formula below.

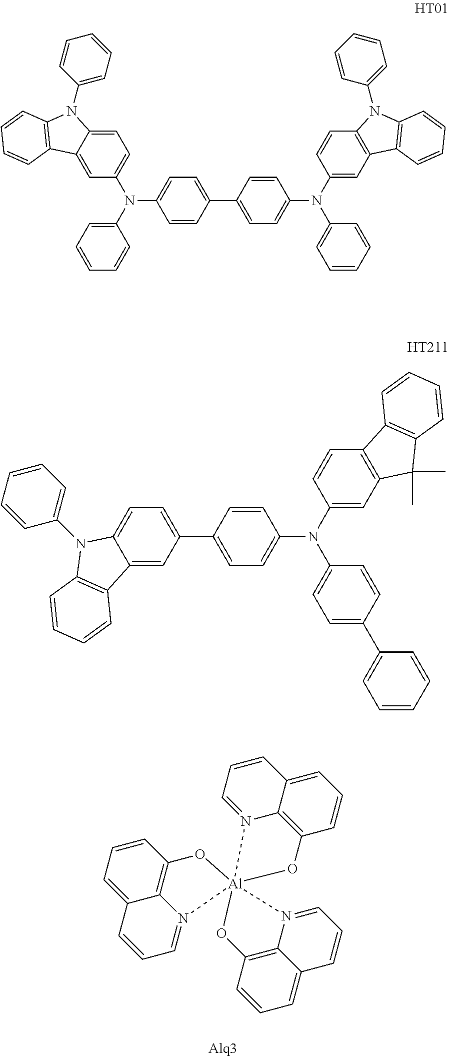

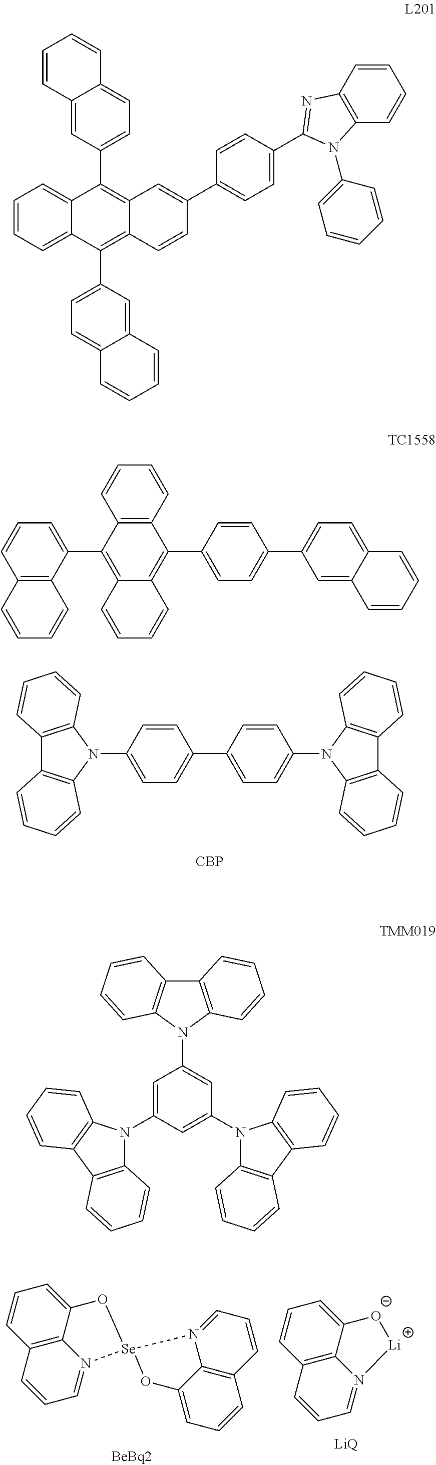

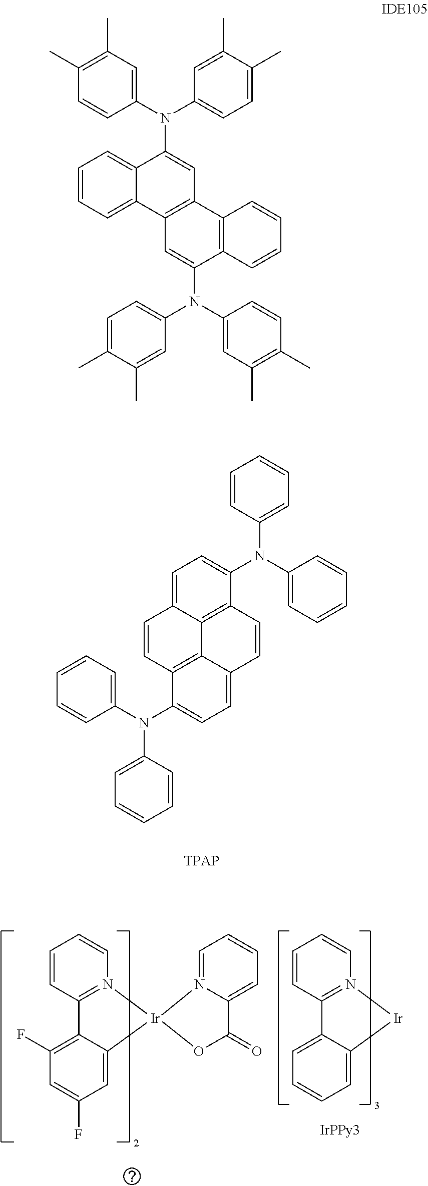

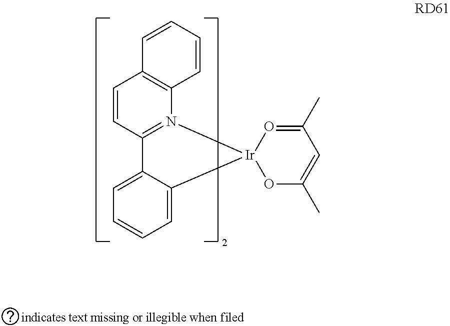

The spacer SP may not contain oxygen O. For example, the spacer SP may not contain any functional groups, hereby preventing moisture absorption. For example, the spacer SP may not contain an-OH functional group, so it may not react with oxygen or moisture. Accordingly, even during the external exposure process of the light emitting layer EML, the spacer SP may not react with oxygen or moisture, thereby blocking ingress of moisture into the light emitting layer EML. Therefore, implementation of the stable display device may be possible.

The inorganic insulating layer IL3 may include an inorganic material, and for example, may include an inorganic insulating material such as silicon nitride SiNₓ, silicon oxide SiOₓ, or silicon oxynitride SiOₓN_{y}.

A second electrode E2 may be positioned on the spacer SP, the first light emitting layer EML1, and the second light emitting layer EML2. The second electrode E2 may be formed to cover the first light emitting layer EML1, the second light emitting layer EML2, and the spacer SP. Since the spacer SP fills a space between the first light emitting layer EML1 and the second light emitting layer EML2, a short circuit in the second electrode E2 may not occur. Therefore, problems such as current leakage or driving errors may be prevented.

The second electrode E2 may be also referred to as a cathode electrode. The second electrode E2 may be a single layer or multilayer including a transparent conductive layer and may include at least one of indium-tin-oxide (ITO), indium-zinc-oxide (IZO), indium-gallium-zinc-oxide (IGZO), and indium-tin-zinc-oxide (ITZO). For example, the second electrode E2 may have a translucent characteristic, in which case it forms a microcavity together with the first electrode E1. According to the microcavity structure, light of a specific wavelength may be emitted upwards according to the spacing and characteristics between the two electrodes, and as a result, red, green or blue may be displayed.

An encapsulating layer ENC may be positioned on the second electrode E2. The encapsulating layer ENC may include at least one inorganic film and at least one organic film.

FIG. 4 illustrates and describes cross-sections of the first pixel area PX1 and the second pixel area PX2, but embodiments are not limited thereto and may be applied to the third pixel area PX3.

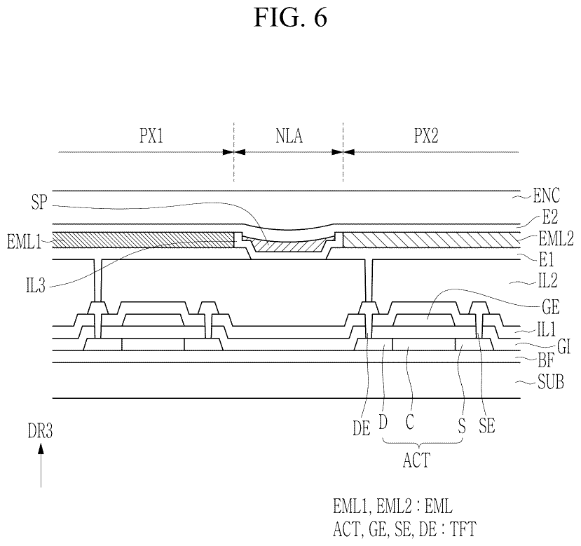

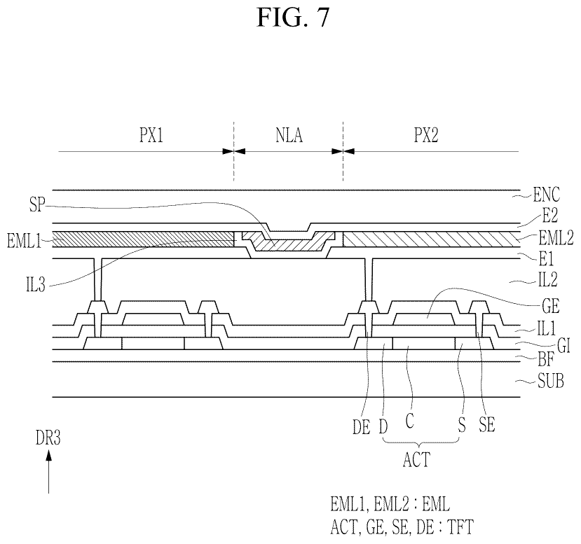

Hereinafter, the display device according to another embodiment will be described with reference to FIGS. 6 and 7. Each of FIGS. 6 and 7 is a schematic cross-sectional view of a portion of the display device. Descriptions of components identical to those given above in FIG. 4 will be omitted for descriptive convenience.

Referring to FIG. 6, the spacer SP may be positioned lower than the light emitting layer EML. The portion positioned at the highest level of the spacer SP may be positioned lower than the portion positioned at the highest level of the light emitting layer EML.

The spacer SP may have a shape that fills part of the concave portion formed by the inorganic insulating layer IL3.

Referring to FIG. 7, at least a portion of the upper surface of the spacer SP may have a downwardly facing concave shape (or a concave shape facing downward). The second electrode E2 positioned on the upper surface of the spacer SP may have a partially stepped shape along the upper surface of the spacer SP. The encapsulating layer ENC may have a form that fills the stepped area of the second electrode E2.

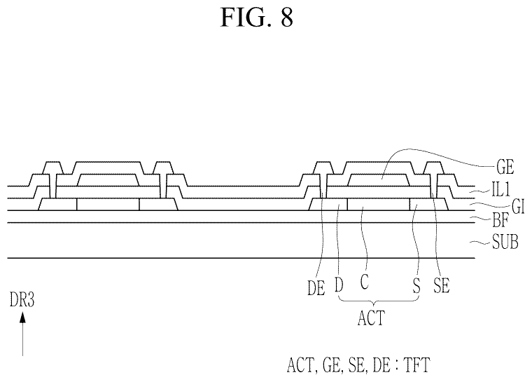

Hereinafter, a method of manufacturing the display device according to an embodiment will be described with reference to FIGS. 8 to 21. FIGS. 8 to 21 are schematic cross-sectional process views sequentially showing a method of manufacturing the display device according to an embodiment. Descriptions of components that are identical to the components given above will be omitted for descriptive convenience.

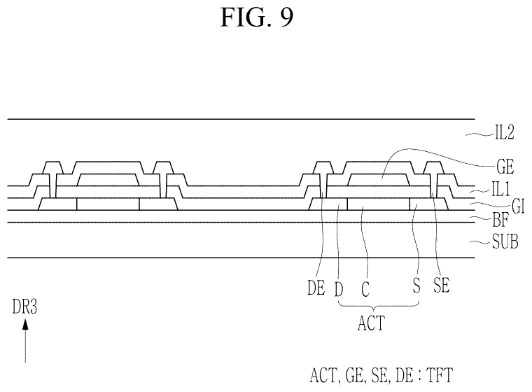

Referring to FIG. 8, a transistor TFT may be positioned on a substrate SUB. Then, as shown in FIG. 9, a second insulating layer IL2 may be positioned on the transistor TFT.

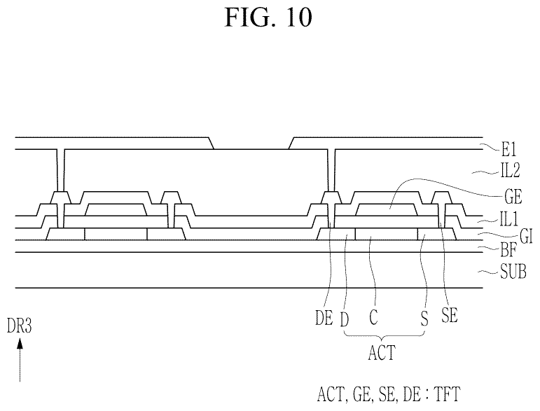

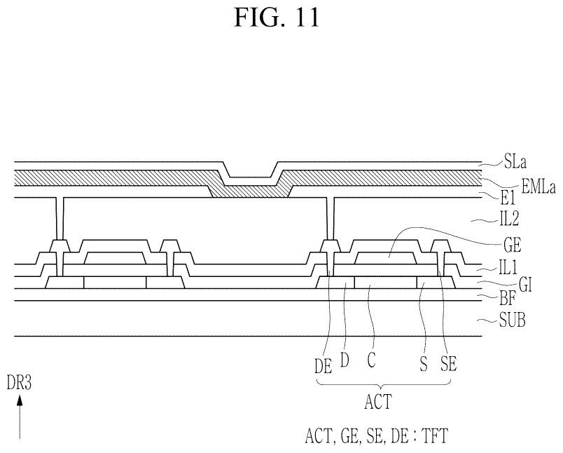

Referring to FIG. 10, the first electrode E1 may be positioned on the second insulating layer IL2. The first electrode E1 may be also referred to as an anode electrode, and, for example, the first electrode E1 may have a three-layer structure of ITO/Ag/ITO. Referring to FIG. 11, a first light emitting material layer EMLa may be stacked on a first electrode E1, and a sacrificial material layer SLa may be stacked on the first light emitting material layer EMLa. The first light emitting material layer EMLa may include, for example, an organic or inorganic material that emits red light. For I example, the first light emitting material layer EMLa may include at least one of a triphenylamine-based compound, carbazole, an aromatic amine-based compound, an anthracene-based compound, hydroxyquinoline, and an iridium complex. The sacrificial material layer SLa may include a metal or metal alloy such as copper (Cu), molybdenum (Mo), aluminum (Al), silver (Ag), chromium (Cr), tantalum (Ta), or titanium (Ti).

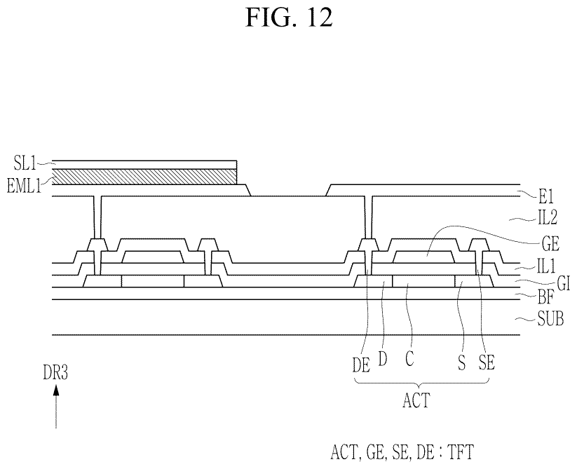

Thereafter, the first light emitting material layer EMLa and the sacrificial material layer SLa may be patterned to form the first light emitting layer EML1 and the first sacrificial layer SL1, as illustrated in FIG. 12. For example, the first light emitting material layer EMLa and the sacrificial material layer SLa may be dry etched to form the first light emitting layer EML1 and the first sacrificial layer SL1, and accordingly, the side surface of the first light emitting layer EML1 may have a high slope. For example, the side surface of the first light emitting layer EML1 may form an inclination angle of about 70° to about 90°, or about 90°, with respect to the substrate SUB. The first light emitting layer EML1 and the first sacrificial layer SL1 may overlap the center portion of the first electrode E1 and may not overlap the edge portion of the first electrode E1. The first light emitting layer EML1 may overlap the first pixel area PX1. The first light emitting layer EML1 may include the first hole injection layer, the first hole transport layer, the first main light emitting layer, the first electron transport layer, and the first electron injection layer.

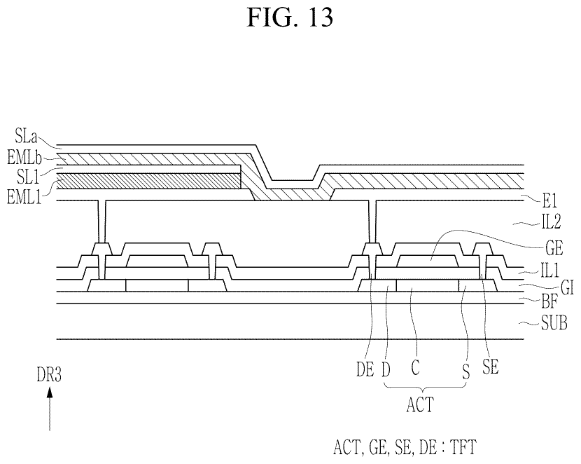

Referring to FIG. 13, a second light emitting material layer EMLb overlapping the entire surface of the substrate SUB may be stacked on the first electrode E1 and the first sacrificial layer SL1, and a sacrificial material layer SLa may be stacked on the second light emitting material layer EMLb. The second light emitting material layer EMLb may include, for example, an organic or inorganic material that emits blue light. For example, the second light emitting material layer EMLb may include at least one of a triphenylamine-based compound, carbazole, an aromatic amine-based compound, an anthracene-based compound, hydroxyquinoline, and an iridium complex.

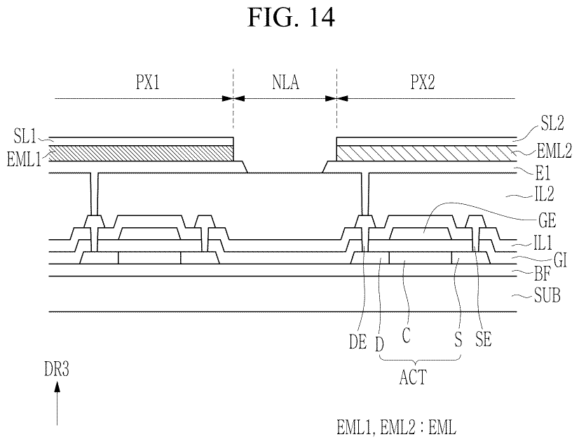

Thereafter, the second light emitting material layer EMLb and the sacrificial material layer SLa may be patterned to form a second light emitting layer EML2 and a second sacrificial layer SL2, as illustrated in FIG. 14. For example, the second light emitting material layer EMLb and the sacrificial material layer SLa may be dry etched to form the second light emitting layer EML2 and the second sacrificial layer SL2, and accordingly, the side surface of the second light emitting layer EML2 may have a high slope. For example, the side surface of the second light emitting layer EML2 may form an inclination angle of about 90° with respect to the substrate SUB. The second light emitting layer EML2 and the second sacrificial layer SL2 may overlap the center portion of the first electrode E1 and may not overlap the edge portion of the first electrode E1. The second light emitting layer EML2 may overlap the second pixel area PX2. The second light emitting layer EML2 may include the second hole injection layer, the second hole transport layer, the second main light emitting layer, the second electron transport layer, and the second electron injection layer.

In case of patterning the first light emitting layer EML1 and the second light emitting layer EML2 using a fine metal mask FMM, a separate protruding support spacer must be provided to support the fine metal mask, and there may be limitations in forming fine openings inside the fine metal mask. Therefore, by using a fine metal mask, foreign substances may remain on the spacer, or the spacer may be damaged, such that the process reliability of the display panel may be lowered. For example, since it is difficult to form a fine-sized light emitting layer, there may be limitations in manufacturing a high-resolution display device.

However, in the display device according to an embodiment, the reliability of the process may be improved by minimizing damage to the first light emitting layer EML1 and the second light emitting layer EML2 by the first sacrificial layer SL1 and the second sacrificial layer SL2 during the process. For example, since the first light emitting layer EML1 and the second light emitting layer EML2 are directly patterned without using a fine metal mask to form a fine size, it is possible to implement a high-resolution display panel.

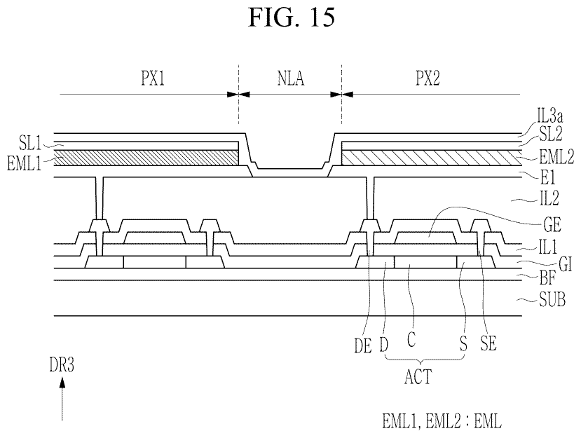

Referring to FIG. 15, an inorganic insulating material layer IL3a overlapping the front surface of the substrate SUB may be stacked on the first sacrificial layer SL1 and the second sacrificial layer SL2, and may be deposited, for example, by a chemical vapor deposition (CVD) process or an atomic layer deposition (ALD) process. The inorganic insulating material layer IL3a may include an inorganic insulating material such as silicon nitride SiNₓ, silicon oxide SiOₓ, or silicon oxynitride SiOₓN_{y}. For example, the thickness of the inorganic insulating material layer IL3a in the third direction DR3 may be about 1000 Å.

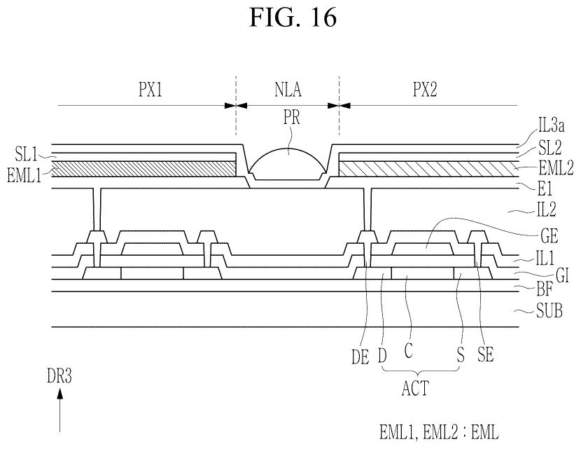

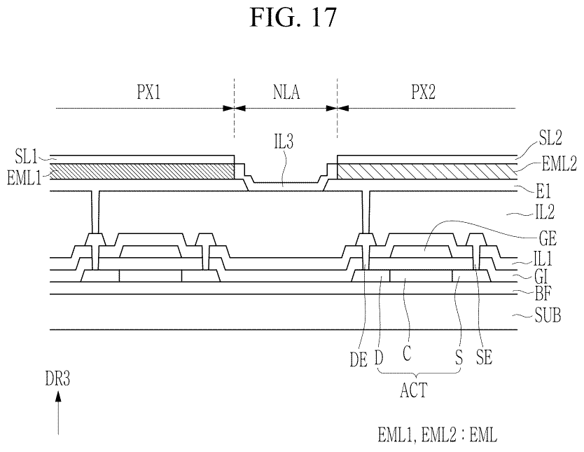

Thereafter, referring to FIGS. 16 and 17, the inorganic insulating material layer IL3a may be patterned to form the inorganic insulating layer IL3. For example, a photosensitive layer PR may be positioned on the inorganic insulating material layer IL3a so as to be spaced apart from the first light emitting layer EML1 and the second light emitting layer EML2. Then, the inorganic insulating material layer IL3a may be etched using the photosensitive layer PR as a mask, forming the inorganic insulating layer IL3 as shown in FIG. 17. In FIG. 16, the inorganic insulating material layer IL3a on the first sacrificial layer SL1 and the second sacrificial layer SL2 may be removed. The photosensitive layer PR may use a photosensitive material that is used at a low temperature, for example, at a temperature lower than the glass transition temperature of the first light emitting layer EML1 and the second light emitting layer EML2. The inorganic insulating layer IL3 may overlap the non-light emitting area NLA. The inorganic insulating layer IL3 may be in contact with the first light emitting layer EML1, the second light emitting layer EML2, and the first electrode E1.

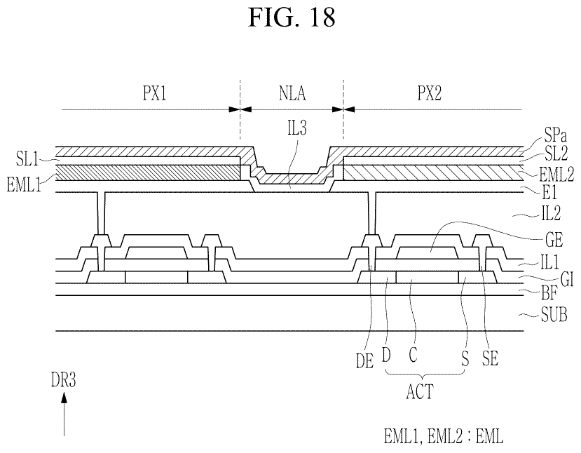

Referring to FIG. 18, a spacer material layer SPa may be stacked on a first sacrificial layer SL1, a second sacrificial layer SL2, and an inorganic insulating layer IL3.

The spacer material layer SPa may have a lower glass transition temperature than the first light emitting layer EML1 and the second light emitting layer EML2. The glass transition temperature of the spacer material layer SPa may be less than 100°, for example, about 90° C. to about 100° C.

The spacer material layer SPa and at least one of the first light emitting layer EML1 or the second light emitting layer EML2 may include the same material. For example, the spacer material layer SPa and at least one of the first hole injection layer, the first hole transport layer, the first main light emitting layer, the first electron transport layer, and the first electron injection layer may include the same material. For example, the spacer material layer SPa and at least one of the second hole injection layer, the second hole transport layer, the second main light emitting layer, the second electron transport layer, and the second electron injection layer may include the same material.

The spacer material layer SPa may include at least one of a triphenylamine-based compound, carbazole, an aromatic amine-based compound, an anthracene-based compound, hydroxyquinoline, and an iridium complex.

For example, the spacer material layer SPa may include at least one selected from a group consisting of HT01, HT211, TC1558, IDE105, TPAP, Alq3, BeBq2, LiQ, F2IrPic, IrPPy3, CBP, TMM019, and RD61, each of which is represented by the chemical formula below.

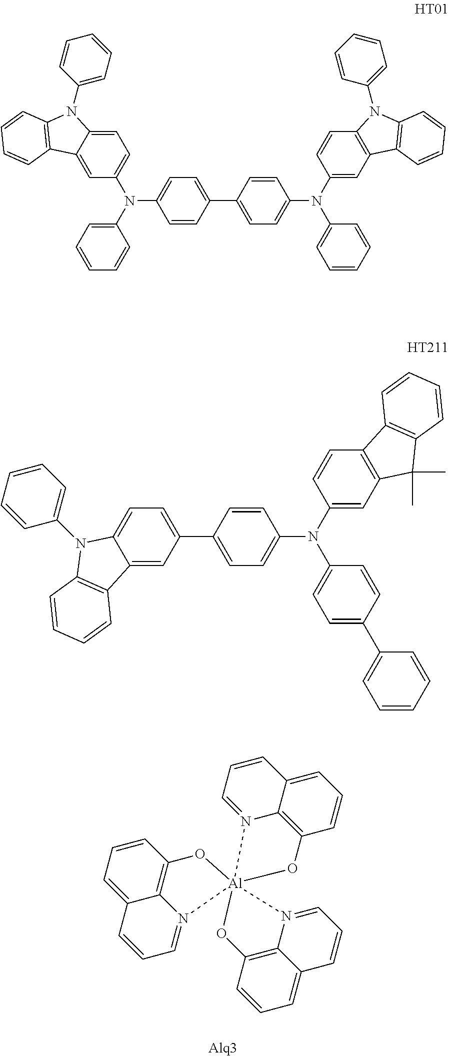

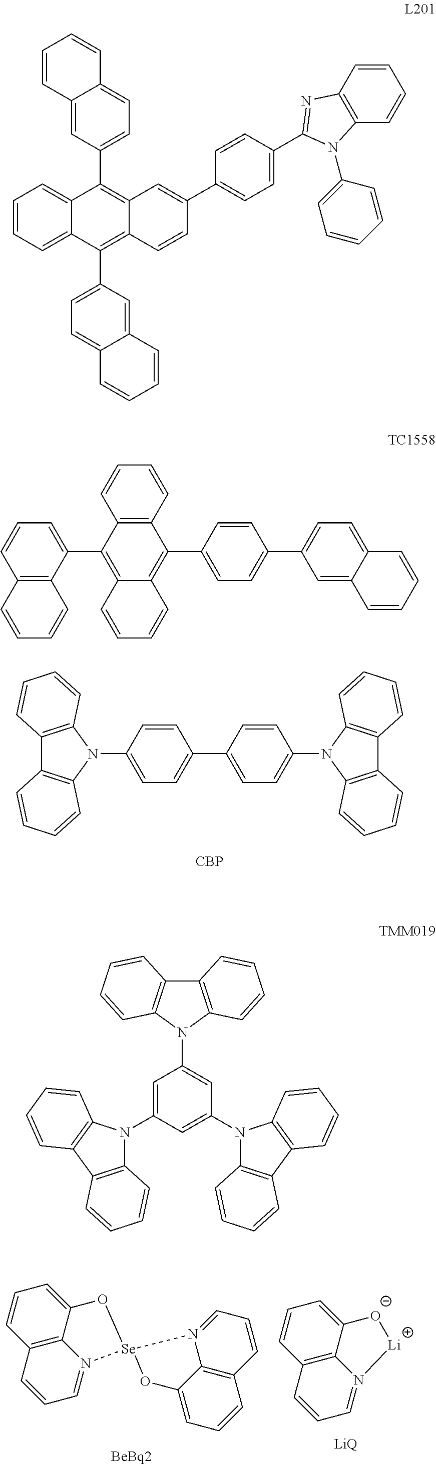

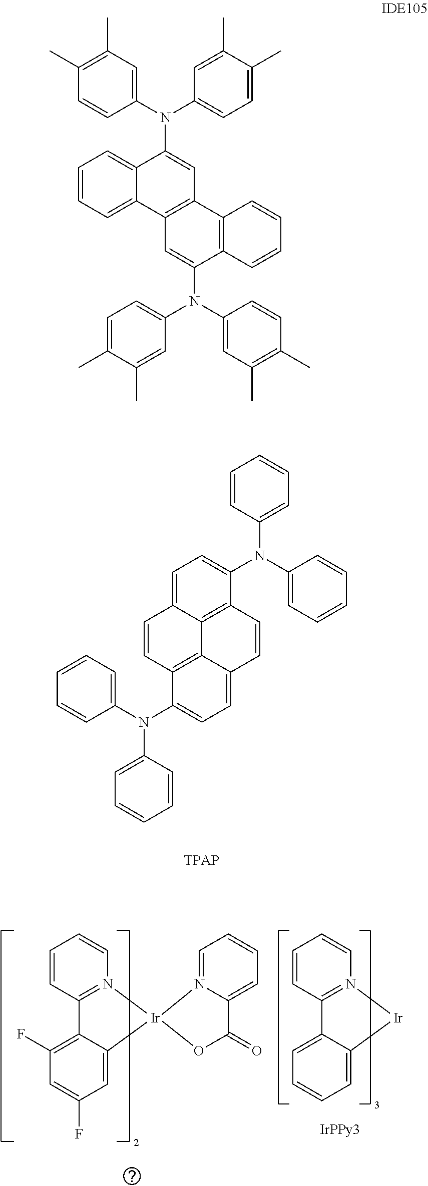

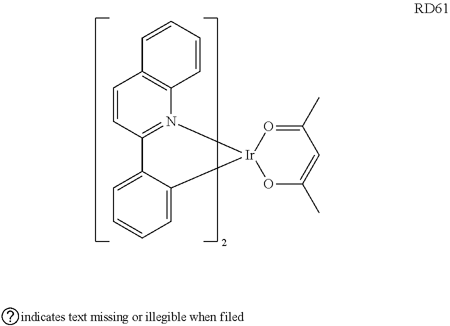

The spacer material layer SPa may not contain oxygen O. For example, the spacer material layer SPa may not contain any functional groups, so moisture absorption may not occur. For example, the spacer material layer SPa may not contain an-OH functional group, so it may not react with oxygen or moisture.

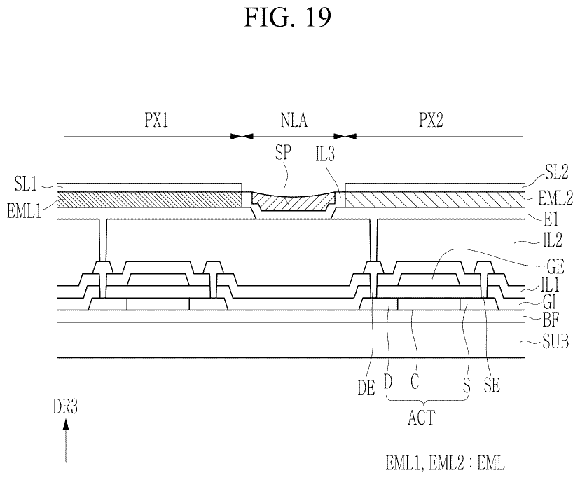

Referring to FIG. 19, the spacer SP may be formed between the first light emitting layer EML1 and the second light emitting layer EML2 through a reflow process. The reflow process may be performed at a temperature higher than a glass transition temperature of the spacer material layer SPa and lower than glass transition temperatures of the first light emitting layer EML1 and the second light emitting layer EML2. For example, the reflow process may be performed at about 90° C. Accordingly, since there is no damage to the first light emitting layer EML1 and the second light emitting layer EML2, the reliability of the process may be improved, enabling the implementation of the stable display device.

At least a portion of the spacer material layer SPa may be fluidized through the reflow process. Accordingly, the spacer SP having a form that fills the inorganic insulating layer IL3 between the first light emitting layer EML1 and the second light emitting layer EML2 may be formed. Furthermore, a residual spacer material layer remaining on the first sacrificial layer SL1 and the second sacrificial layer SL2 may be removed through a cleaning process. For example, the residual spacer material layer may be removed through an ashing process.

The spacer SP may have various shapes as described above in FIGS. 4, 6 and 7.

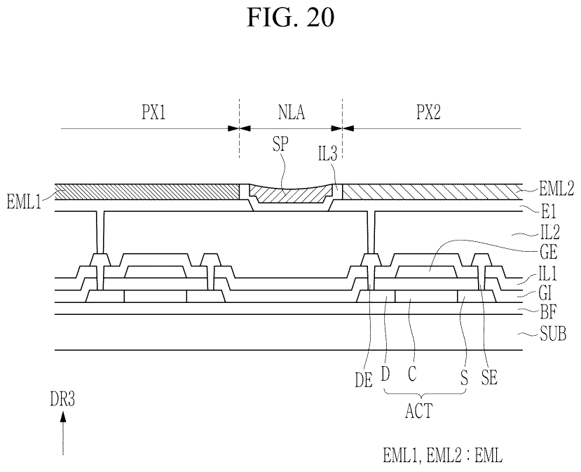

Thereafter, referring to FIG. 20, the first sacrificial layer SL1 and the second sacrificial layer SL2 may be removed. For example, the first sacrificial layer SL1 and the second sacrificial layer SL2 may be removed by wet etching using a phosphoric acid H3PO4 solution. For example, although the first sacrificial layer SL1 and the second sacrificial layer SL2 are removed, the spacer SP may not contain oxygen O, so it may block moisture from entering the first light emitting layer EML1 and the second light emitting layer EML2. For example, since the spacer SP does not contain an-OH functional group, it may not react with oxygen and moisture, so the first light emitting layer EML1 and the second light emitting layer EML2 may not be damaged even during the external exposure process. Therefore, implementation of the stable display device may be possible.

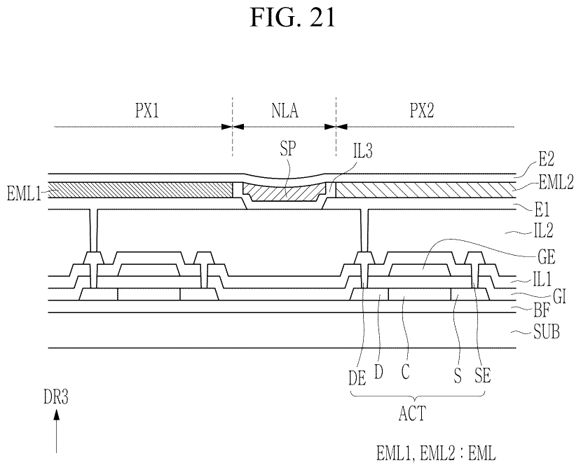

Referring to FIG. 21, the second electrode E2 may be formed on the first light emitting layer EML1 and the second light emitting layer EML2, and, for example, the second electrode E2 may be deposited in a vacuum chamber. The second electrode E2 may be a single layer or multilayer including a transparent conductive layer and may include at least one of indium-tin-oxide (ITO), indium-zinc-oxide (IZO), indium-gallium-zinc-oxide (IGZO), and indium-tin-zinc-oxide (ITZO).

The second electrode E2 may be formed to cover the first light emitting layer EML1, the second light emitting layer EML2, and the spacer SP. Since the spacer SP fills the space between the first light emitting layer EML1 and the second light emitting layer EML2, a short circuit in the second electrode E2 may not occur. Therefore, problems such as current leakage or driving errors may be prevented.

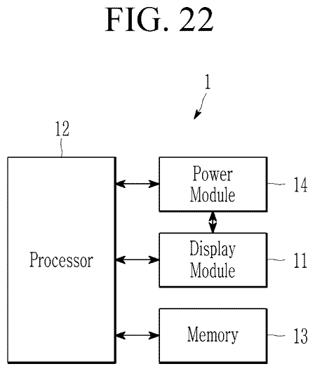

FIG. 22 is a block diagram of an electronic device according to an embodiment. Referring to FIG. 22, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operations of the processor 12 or the display module 11. In case that the processor 12 executes an application stored in the memory 13, video data signals and/or input control signals are transmitted to the display module 11, and the display module 11 may process the received signals to output video information through the display screen.

The power module 14 may include a power supply module such as a power adapter or battery device, and a power conversion module that converts the power supplied by the power supply module to generate the power necessary for the operation of the electronic device 1.

At least one of components of the electronic device 1 may be included within the display device 1000 according to the above-described embodiments. Some of the individual modules that are functionally included within a single module may be incorporated into the display device 1000, while others may be provided separately from the display device 1000. For example, the display device 1000 may include the display module 11, while the processor 12, memory 13, and power module 14 may be provided in a form of other devices within the electronic device 1 that are not part of the display device 1000.

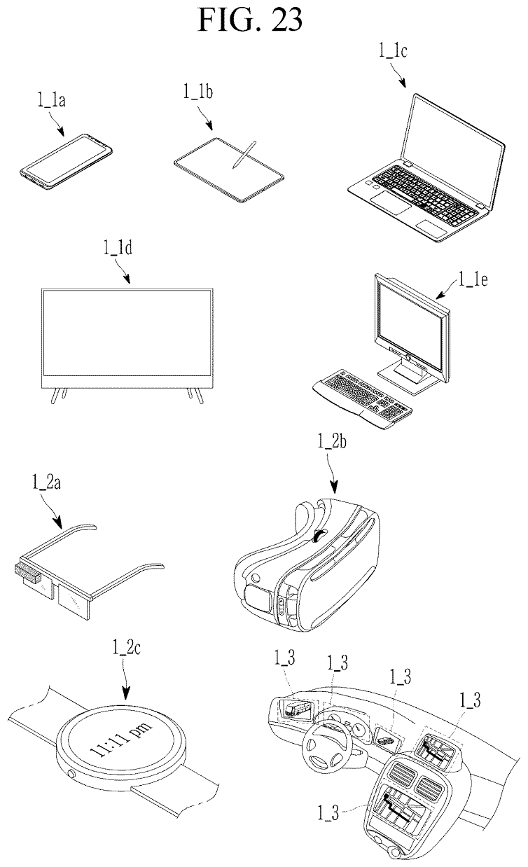

FIG. 23 shows schematic diagrams of electronic devices according to various embodiments.

Referring to FIG. 23, various electronic devices with the display device 1000 according to the embodiments may include not only image display electronic devices such as smartphones 1_1a, tablet PCs 1_1b, laptops 1_1c, TVs 1_1d, desktop monitors 1_1e, but also wearable electronic devices with display modules such as smart glasses 1_2a, head-mounted displays 1_2b, smart watches 1_2c, as well as automotive electronic devices with display modules 1_3 such as those placed on car dashboards, center fascias, CID (Center Information Display), room mirror displays, and so on.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate including a first pixel area and a second pixel area;
a first electrode disposed on the substrate;
a first light emitting layer disposed on the first pixel area;
a second light emitting layer disposed on the second pixel area;
a spacer disposed between the first light emitting layer and the second light emitting layer;
an inorganic insulating layer disposed between the first light emitting layer and the spacer, and between the second light emitting layer and the spacer, and
a second electrode disposed on the first light emitting layer and the second light emitting layer,
wherein the spacer and at least one of the first light emitting layer and the second light emitting layer include a same material.

2. The display device of claim 1, wherein:
side surfaces of the first light emitting layer and the second light emitting layer form an inclination angle in a range of about 70° to about 90° with respect to the substrate.

3. The display device of claim 1, wherein:
the spacer has a glass transition temperature lower than those of the first light emitting layer and the second light emitting layer.

4. The display device of claim 3, wherein:
the glass transition temperature of the spacer is in a range of about 90° C. to about 100° C.

5. The display device of claim 1, wherein:
the first light emitting layer includes at least one of a first hole injection layer, a first hole transport layer, a first main light emitting layer, a first electron transport layer, and a first electron injection layer.

6. The display device of claim 5, wherein:
the second light emitting layer includes at least one of a second hole injection layer, a second hole transport layer, a second main light emitting layer, a second electron transport layer, and a second electron injection layer.

7. The display device of claim 6, wherein:
the spacer and at least one of the first hole injection layer, the first hole transport layer, the first main light emitting layer, the first electron transport layer, the first electron injection layer, the second hole injection layer, the second hole transport layer, the second main light emitting layer, the second electron transport layer, and the second electron injection layer include a same material.

8. The display device of claim 1, wherein:
the spacer is in a form of filling the inorganic insulating layer.

9. The display device of claim 1, wherein:
the spacer comprises at least one of triphenylamine compounds, carbazole, aromatic amine compounds, anthracene compounds, hydroxyquinoline, and iridium complexes.

10. The display device of claim 1, wherein:
the spacer does not contain oxygen.

11. The display device of claim 1, wherein:
an upper surface of the spacer is downwardly concave without a step from the first light emitting layer and the second light emitting layer.

12. The display device of claim 1, wherein:
an upper surface of the spacer is disposed lower than upper surfaces of the first light emitting layer and the second light emitting layer.

13. The display device of claim 1, wherein:
the second electrode covers the first light emitting layer, the second light emitting layer, and the spacer.

14. A method of manufacturing a display device, the method comprising:
preparing a substrate including a first pixel area and a second pixel area,
forming a first electrode on the substrate,
forming a first light emitting layer overlapping the first pixel area on the first electrode, and a first sacrificial layer disposed on the first light emitting layer;
forming a second light emitting layer overlapping the second pixel area on the first electrode, and a second sacrificial layer disposed on the second light emitting layer;
forming an inorganic insulating layer between the first light emitting layer and the second light emitting layer;
forming a spacer material layer on the first and second sacrificial layers and the inorganic insulating layer;
forming a spacer between the first light emitting layer and the second light emitting layer through a reflow process;
removing the spacer material layer remaining on the first sacrificial layer and the second sacrificial layer;
removing the first sacrificial layer and the second sacrificial layer, and
forming a second electrode on the first light emitting layer, the second light emitting layer, and the spacer,
wherein the spacer and at least one of the first light emitting layer and the second light emitting layer include a same material.

15. The method of claim 14, wherein:
the forming of the spacer between the first light emitting layer and the second light emitting layer through a reflow process comprises filling a space between the first light emitting layer and the second light emitting layer with at least a portion of the spacer material layer having fluidity, and
the reflow process is performed at a temperature lower than a glass transition temperature of the first light emitting layer and the second light emitting layer and higher than a glass transition temperature of the spacer forming layer.

16. The method of claim 14, wherein:
the first light emitting layer includes at least one of a first hole injection layer, a first hole transport layer, a first main light emitting layer, a first electron transport layer, and a first electron injection layer,
the second light emitting layer includes at least one of a second hole injection layer, a second hole transport layer, a second main light emitting layer, a second electron transport layer, and a second electron injection layer,
the spacer and at least one of the first hole injection layer, the first hole transport layer, the first main light emitting layer, the first electron transport layer, the first electron injection layer, the second hole injection layer, the second hole transport layer, the second main light emitting layer, the second electron transport layer, and the second electron injection layer include a same material.

17. The method of claim 14, wherein:
the forming of the first light emitting layer and the first sacrificial layer overlapping the first pixel area on the first electrode comprises:
stacking a first light emitting material layer on the first electrode,
stacking a first sacrificial material layer on the first light emitting material layer, and
forming the first light emitting layer and the first sacrificial layer by patterning the first light emitting material layer and the first sacrificial material layer,
the forming of the second light emitting layer and the second sacrificial layer overlapping the second pixel area on the first electrode comprises:
depositing a second light emitting material layer on the first electrode,
depositing a second sacrificial material layer on the second light emitting material layer, and
forming the second light emitting layer and the second sacrificial layer by patterning the second light emitting material layer and the second sacrificial material layer, and
side surfaces of the first light emitting layer and the second light emitting layer form an inclination angle of about 70° to about 90° with respect to the substrate.

18. The method of claim 14, wherein:
the spacer comprises at least one of a triphenylamine-based compound, carbazole, an aromatic amine-based compound, an anthracene-based compound, hydroxyquinoline, and an iridium complex.

19. The method of claim 14, wherein:
the spacer does not contain oxygen.

20. An electronic device comprising:
a processor that provides input image data; and
a display device that displays an image based on the input image data, the display device comprising:
a substrate including a first pixel area and a second pixel area;
a first electrode disposed on the substrate;
a first light emitting layer disposed on the first pixel area;
a second light emitting layer disposed on the second pixel area;
a spacer disposed between the first light emitting layer and the second light emitting layer;
an inorganic insulating layer disposed between the first light emitting layer and the spacer, and between the second light emitting layer and the spacer, and
a second electrode disposed on the first light emitting layer and the second light emitting layer,
wherein the spacer and at least one of the first light emitting layer and the second light emitting layer include a same material.
